(19) United States
(12) Patent Application Publication
(10) Pub. No.: US 2026/0173414 A1
(43) Pub. Date: Jun. 18, 2026

(54) SEMICONDUCTOR DEVICE AND METHOD OF MANUFACTURING THE SAME

(71) Applicant: Taiwan Semiconductor Manufacturing Company, Ltd., Hsinchu (TW)

(72) Inventors: Hsiang-Lin Chen, Hsinchu County (TW); Hsing-Chih Lin, Tainan City (TW); Ko Chun Liu, Toufen Township (TW); Meng-Hsien Lin, Tainan City (TW)

(21) Appl. No.: 18/981,781

(22) Filed: Dec. 16, 2024

(51) Int. Cl. H10D 1/68; H10D 1/00; H10D 84/00; H10D 88/00

(52) U.S. Cl. CPC H10D 1/714; H10D 1/042; H10D 84/212; H10D 88/00

(57) ABSTRACT

Some embodiments relate to an integrated circuit (IC) device that includes a substrate and a capacitor structure. The capacitor structure includes a first conductive element disposed over the substrate, where the first conductive element includes a plurality of trenches extending downward from an upper side of the first conductive element toward the substrate. A thickness of the first conductive element between adjacent ones of the plurality of trenches is greater than or equal to a depth of the plurality of trenches. The capacitor structure further includes a dielectric element disposed on the upper side of the first conductive element and extending into the plurality of trenches, and a second conductive element disposed on the dielectric element and extending into the plurality of trenches.

### BACKGROUND

One area of focus in integrated circuit (IC) technology has been the improvement (e.g., in terms of density, footprint, and so on) of capacitors employed within an IC device. One advancement in this area is the three-dimensional (3D) metal-insulator-metal (MIM) capacitor, which implements a capacitor that possesses a high-level of conductor surface area relative to the volume such a capacitor consumes within the IC device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B illustrate a side view and a plan view, respectively, of some embodiments of a three-dimensional (3D) metal-insulator-metal (MIM) capacitor structure having a bulk conductive element including deep trenches with angled sidewalls, according to the present disclosure.

FIG. 1C illustrates a plan view of the 3D-MIM capacitor of FIG. 1A having a bulk conductive element including deep and elongated trenches with angled sidewalls, according to the present disclosure.

FIGS. 2A and 2B illustrate a side view and a plan view, respectively, of some embodiments of a 3D-MIM capacitor structure having a bulk conductive element including shallow trenches with angled sidewalls, according to the present disclosure.

FIGS. 3A and 3B illustrate a side view and a plan view, respectively, of some embodiments of a 3D-MIM capacitor structure having a bulk conductive element including deep trenches with vertical sidewalls, according to the present disclosure.

FIGS. 4A and 4B illustrate a side view and a plan view, respectively, of some embodiments of a 3D-MIM capacitor structure having a bulk conductive element including shallow trenches with vertical sidewalls, according to the present disclosure.

FIG. 5 illustrates a side view of some embodiments of a CMOS image sensor (CIS) integrated circuit (IC) device including a plurality of 3D-MIM capacitor structures, each having a bulk conductive element, according to the present disclosure.

FIGS. 6A through 6M illustrate various side views of some embodiments of an IC device including a 3D-MIM capacitor structure having a bulk conductive element at various stages of manufacture, according to the present disclosure.

FIG. 7 illustrates a methodology of forming an IC device including a 3D-MIM capacitor structure having a bulk conductive element, according to some embodiments of the present disclosure.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

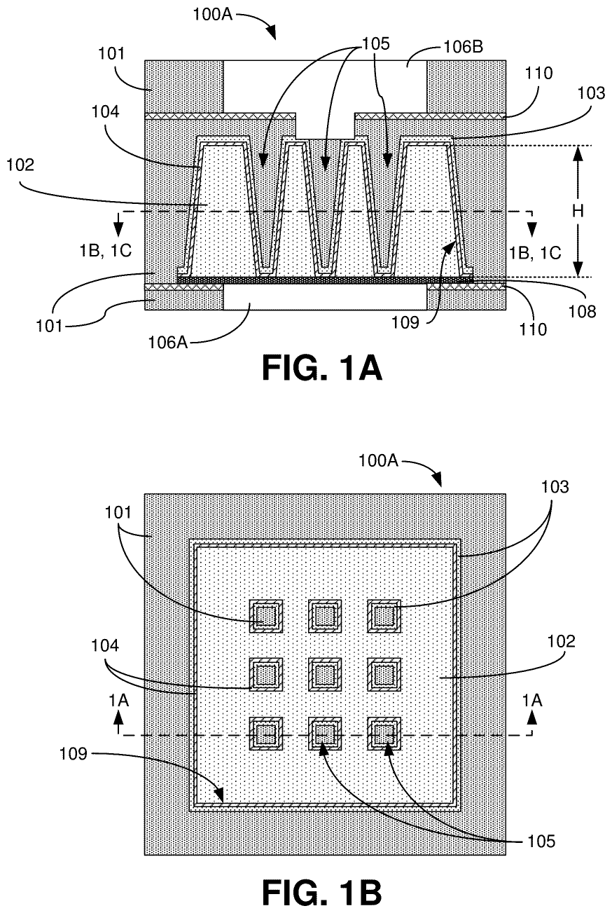

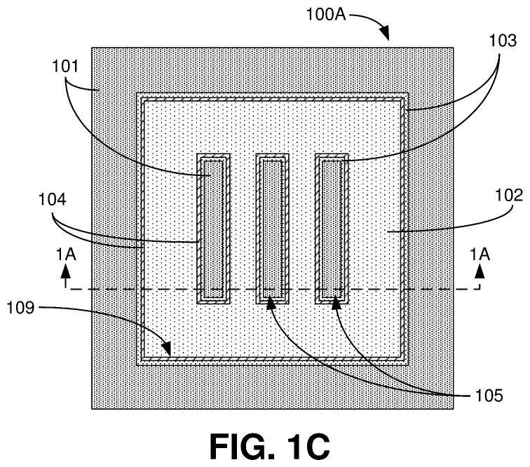

FIGS. 1A, 1B, 2A, 2B, 3A, 3B, 4A, and 4B illustrate various views of some embodiments of three-dimensional (3D) metal-insulator-metal (MIM) capacitor structures 100A, 100B, 100C, and 100D (collectively, 3D-MIM capacitor structure 100) employed within an integrated circuit (ID) device, according to the present disclosure. In the embodiments, a first (e.g., lower or bottom) “bulk” conductive element 102 is employed as one of the “metal” components of the 3D-MIM capacitor structure 100. Further, bulk conductive element 102 may include a plurality of trenches 105 that may extend downward partially into, or completely through, bulk conductive element 102. Further, a thickness of bulk conductive element 102 between or among the plurality of trenches 105 may be greater than or equal to a depth of the plurality of trenches 105. Thereafter, an insulating (e.g., dielectric) element 104 and a second conductive element 103 may be disposed conformally over bulk conductive element 102, with dielectric element 104 and second conductive element 103 following the contour of each of the plurality of trenches 105 of bulk conductive element 102. As employed herein, the term “bulk” generally refers to a structure having sufficient thickness (e.g., in the vertical direction, as depicted in FIGS. 1A, 2A, 3A, and 4A) to include trenches or similar features in which other IC materials (e.g., dielectric material, conductive material, and so on) may be located, disposed, or formed.

In at least some embodiments, the use of bulk conductive element 102 may reduce the overall process cost of providing 3D-MIM capacitor structure 100 by reducing the number of material layers to be deposited within a trench or hole-like structure. Further, the use of bulk conductive element 102, which may possess a relatively large lower side, may facilitate a relatively large surface area for providing an electrical connection with a bottom electrode, thus potentially reducing the risk of an open circuit connection between 3D-MIM capacitor structure 100 and the bottom electrode. Other benefits or advantages of the use of bulk conductive element 102, as opposed to a comparatively thin conductive element provided atop a trenched dielectric layer, as a capacitor bottom metal element, are also possible.

FIGS. 1A and 1B illustrate a side view and a plan view, respectively, of some embodiments of a 3D-MIM capacitor structure 100A having a bulk conductive element 102 (e.g., serving as a capacitor bottom metal (CBM) structure) including deep trenches 105 with angled sidewalls, according to the present disclosure. In some embodiments, as depicted in FIG. 1B, trenches 105 may be arranged as a rectangular (e.g., square) two-dimensional (2D) array in the plan view of 3D-MIM capacitor structure 100A, such as a 3-by-3 array. In other embodiments, any number of trenches 105 may be arranged as a rectangular array (e.g., a 2-by-2 array, a 2-by-3 array, a 3-by-2 array, a 4-by-4 array, and so forth). In yet other embodiments, trenches 105 may be separate (e.g., non-overlapping) and arranged into any configuration in the plan view.

In some embodiments, bulk conductive element 102 may include titanium nitride (TiN), an aluminum-copper (AlCu) alloy, tungsten (W), and/or another metal or metal alloy, and/or another conductive material.

Further, in some embodiments, while a shape of each trench 105 is shown to be square in the plan view of FIG. 1B, each trench 105 may possess any other 2D shape (e.g., rectangular, circular, and so on) in the plan view in other embodiments.

In some embodiments, as illustrated in FIG. 1A, each trench 105 may have one or more (e.g., four) sidewalls facing toward an inner region of trench 105. Further, in some embodiments, bulk conductive element 102 may have an outer wall 109 at an external perimeter of bulk conductive element 102 that faces away from trenches 105.

Further, as depicted in FIG. 1A, the sidewalls of trenches 105 and outer wall 109 of bulk conductive element 102 may be angled relative to the vertical direction (e.g., such that the face of each sidewall and outer wall 109 face slightly upward). In some embodiments, the angled sidewalls and outer wall 109 may be formed by way of an angled (e.g., anisotropic) etching technique. In some embodiments, the angled sidewalls and outer wall 109 may facilitate the deposition of additional structural layers, such as a dielectric (e.g., insulating) element 104 and a second (e.g., upper) conductive element 103, as discussed more fully below. Additionally, as shown in FIG. 1A, each trench 105 may extend completely through bulk conductive element 102 (e.g., where bulk conductive element 102 may have an overall thickness or height, labeled as ‘H’) to an underlying layer (e.g., a conductive barrier layer 108). In some embodiments, H may be in the range of approximately 0.2 microns (μm) to approximately 2.0 μm, although other values for H are also possible.

In some embodiments, a dielectric (e.g., insulating) element 104 may be conformally disposed (e.g., as a film) over (e.g., atop) bulk conductive element 102. Consequently, in some embodiments, dielectric element 104 may cover (e.g., contact) an upper side of bulk conductive element 102, including the sidewalls and bottom of each trench 105, as well as outer wall 109, of bulk conductive element 102. Further, in some embodiments, dielectric element 104 may include a high-dielectric-constant (high-kappa, or high-κ) dielectric material, such as hafnium silicate (HfO₆Si₂), zirconium silicate (ZrSiO₄), hafnium dioxide (HfO₂), zirconium dioxide (ZrO₂), and/or the like. In other embodiments, dielectric element 104 may include other dielectric materials that are not high-κ dielectric or insulating materials.

Further, in other embodiments, a conductive element 103 (e.g., a second or upper conductive element serving as a capacitor top metal (CTM) structure) may be conformally disposed (e.g., as a film) over (e.g., atop) dielectric element 104. As a result, in some embodiments, conductive element 103 may cover (e.g., contact) an upper side of dielectric element 104, including covering the portions of dielectric element 104 residing within trenches 105 and on outer wall 109 of bulk conductive element 102. Additionally, in some embodiments, conductive element 106 may include titanium nitride (TiN), an aluminum-copper (AlCu) alloy, tungsten (W), and/or another metal or metal alloy, and/or another conductive material.

Consequently, in some embodiments, dielectric element 104 and conductive element 103 may each be viewed as including trenches that substantially coincide with (e.g., extend into) trenches 105 of bulk conductive element 102.

Accordingly, with bulk conductive element 102 and conductive element 103 being separated by dielectric element 104, the basic components of 3D-MIM capacitor 100A are provided. To facilitate connection of bulk conductive element 102 and conductive element 103 with other circuitry within an IC device, in some embodiments, as depicted in FIG. 1A, a first electrode 106A may be conductively connected with a lower side of bulk conductive element 102 (e.g., via a conductive barrier layer 108). Also, in some embodiments, a second electrode 106B may be conductively connected with conductive element 103. Consequently, first electrode 106A and second electrode 106B may provide connection structures that other circuitry within an IC device may employ to connect to 3D-MIM capacitor structure 100A. In some embodiments, first electrode 106A and/or second electrode 106B may include copper (Cu) and/or another metal and/or metal alloy, and/or another conductive material.

In some embodiments, first electrode 106A may serve as a portion of a metal layer residing within a dielectric structure 101. As illustrated in FIGS. 1A and 1B, one or more dielectric structures 101 may also surround or encapsulate one or more other components of 3D-MIM capacitor structure 100A (e.g., bulk conductive element 102, dielectric element 104, conductive element 103, and/or conductive barrier layer 108). Further, conductive barrier layer 108 may be disposed over (e.g., on) first electrode 106A. Also, in some embodiments, conductive barrier layer 108 may serve as a platform upon which bulk conductive element 102 may be deposited. Additionally, conductive barrier layer 108 may serve as an etch stop layer when forming trenches 105, as indicated to best effect in FIG. 1A. In some embodiments, conductive barrier layer 108 may include tantalum (Ta), tantalum nitride (TaN), a combination thereof, one or more metals or metal alloys, and/or one or more other conductive materials.

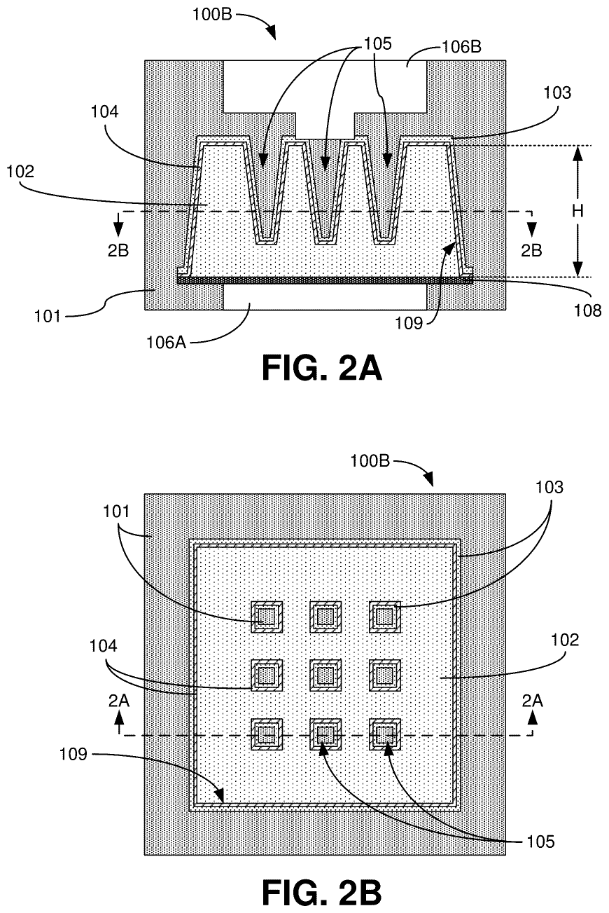

Further, as shown in FIG. 1A, in some embodiments, one or more etch stop layers 110 may be included with the one or more dielectric structures 101 (e.g., to aid in forming the various layers of material for 3D-MIM capacitor structure 100A and second electrode 106B). In other embodiments, etch stop layers 110 may be omitted. While etch stop layers 110 are not explicitly shown in the embodiments of FIGS. 2A and 2B, FIGS. 3A and 3B, and FIGS. 4A and 4B, such layers may be employed in corresponding embodiments.

Second electrode 106B, in some embodiments, may be disposed over (e.g., on or atop) conductive element 103, as depicted in FIG. 1A. Further, second electrode 106B may include a lower portion (e.g., serving as a conductive via of an IC device) and a wider, connected upper portion (e.g., serving as a portion of a metal layer of the IC device). In some embodiments, bulk conductive element 102 and first electrode 106A may be aligned with a metal layer of the IC device that includes 3D-MIM capacitor structure 100A. Further, the upper portion of second electrode 106B may be aligned with a higher metal layer than the metal layer with which first electrode 106A is aligned. Additionally, in some embodiments, the lower portion of second electrode 106B may extend downward partially into conductive element 103 (e.g., to provide a greater amount of surface area of contact between second electrode 106B and conductive element 103).

In some embodiments, the lower portion of second electrode 106B may contact less than all of an upper side of bulk conductive element 102. For example, in some embodiments, as depicted in FIG. 1A, a lower surface of the lower portion of second electrode 106B may contact a portion of the upper side of bulk conductive element 102 that surrounds a centrally located trench 105, but is interior to others of the trenches 105. In other embodiments, the lower surface of the lower portion of second electrode 106B may contact a portion of the upper side of bulk conductive element 102 that surrounds all trenches 105. In yet other embodiments, the lower surface of the lower portion of second electrode 106B may contact a portion of the upper side of bulk conductive element 102 that surrounds some, but not all, trenches 105.

As an alternative to FIG. 1B, FIG. 1C illustrates a plan view of 3D-MIM capacitor 100A of FIG. 1A having a bulk conductive element 102 including deep and elongated trenches with angled sidewalls, according to the present disclosure. More specifically, instead of trenches 105 forming squares in a plan view of the IC device, as depicted in FIG. 1B, trenches 105 may appear as elongated (e.g., rectangular) features in the plan view.

FIGS. 2A and 2B illustrate a side view and a plan view, respectively, of some embodiments of a 3D-MIM capacitor structure 100B having a bulk conductive element 102 including shallow trenches 105 with angled sidewalls, according to the present disclosure. In some embodiments, each of shallow trenches 105 does not extend to a lower side of bulk conductive element 102 (e.g., at conductive barrier layer 108). Rather, shallow trenches 105 are separated from a bottom of bulk conductive element 102 by a non-zero distance, so that bulk conductive element 102 extends below shallow trenches 105. In some embodiments, bulk conductive element 102 may have a height within shallow trenches 105 that is less than half of the height of bulk conductive element 102 laterally outside of shallow trenches 105. In some embodiments, shallow trenches 105 may extend at least halfway between an upper side of bulk conductive element 102 and a lower side of bulk conductive element 102 (e.g., at conductive barrier layer 108). Accordingly, the depth of trenches 105 may be greater than or equal to approximately 0.5H and less than H, as illustrated in FIG. 2A. Further, in some embodiments, the depth of shallow trenches 105 may be selected such that 3D-MIM capacitor structure 100B may provide a corresponding amount of capacitance (e.g., by altering the overall surface area of trenches 105, within which dielectric element 104 and conductive element 103 are deposited) without altering the footprint of 3D-MIM capacitor structure 100B in a plan view.

In some embodiments, bulk conductive element 102 may have a plurality of protrusions extending outward from lower surfaces of bulk conductive element 102 that form shallow trenches 105, in a cross-sectional view. The plurality of protrusions are separated by shallow trenches 105. In some embodiments, the plurality of protrusions may have different widths. For example, the plurality of protrusions may comprise one or more central protrusions that have smaller widths than peripheral protrusions.

In some embodiments, a lower portion of second electrode 106B contacts conductive element 103. In some embodiments, the lower portion of the second electrode 106B may extend along a sidewall of conductive element 103. In some embodiments, the lower portion of second electrode 106B may comprise a first lower surface vertically contacting an upper surface of conductive element 103 and a second lower surface arranged laterally outside of the upper surface of conductive element 103 and below the first lower surface. In some embodiments, a part of the lower portion of second electrode 106B may be laterally separated from conductive element 103 by dielectric element 104.

Other aspects regarding bulk conductive element 102 (e.g., including trenches 105 and outer wall 109), dielectric element 104, conductive element 103, conductive barrier layer 108, first electrode 106A, second electrode 106B, and dielectric structure 101 of 3D-MIM capacitor structure 100A, as illustrated in FIGS. 1A and 1B and as discussed above, may be applicable to 3D-MIM capacitor structure 100B of FIGS. 2A and 2B.

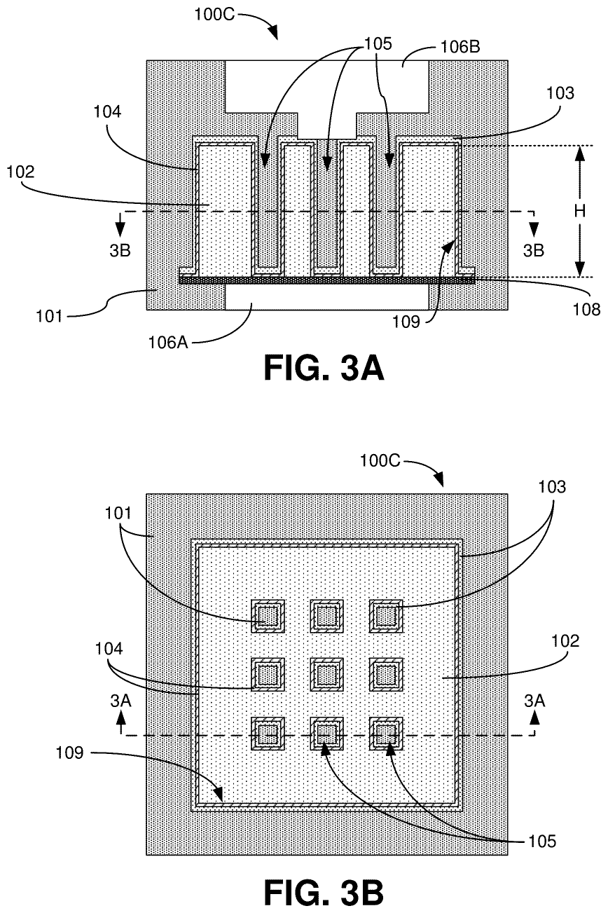

FIGS. 3A and 3B illustrate a side view and a plan view, respectively, of some embodiments of a 3D-MIM capacitor structure 100C having a bulk conductive element 102 including deep trenches 105 with vertical sidewalls, according to the present disclosure. In some embodiments, like the angled sidewalls of trenches 105 of 3D-MIM capacitor structure 100A of FIGS. 1A and 1B, trenches 105, as well as outer wall 109, of 3D-MIM capacitor structure 100C may be formed in bulk conductive element 102 by way of a vertical (e.g., anisotropic) etching technique. In some embodiments, the vertical sidewalls and outer wall 109 may facilitate the deposition of additional structural layers, such as a dielectric element 104 and second conductive element 103. Additionally, as discussed above in connection with 3D-MIM capacitor structure 100A shown in FIG. 1A, each trench 105 may extend completely through bulk conductive element 102 to an underlying layer (e.g., conductive barrier layer 108).

Other aspects regarding bulk conductive element 102 (e.g., including trenches 105 and outer wall 109), dielectric element 104, conductive element 103, conductive barrier layer 108, first electrode 106A, second electrode 106B, and dielectric structure 101 of 3D-MIM capacitor structure 100A, as discussed above in conjunction with FIGS. 1A and 1B, may be applicable to 3D-MIM capacitor structure 100C of FIGS. 3A and 3B.

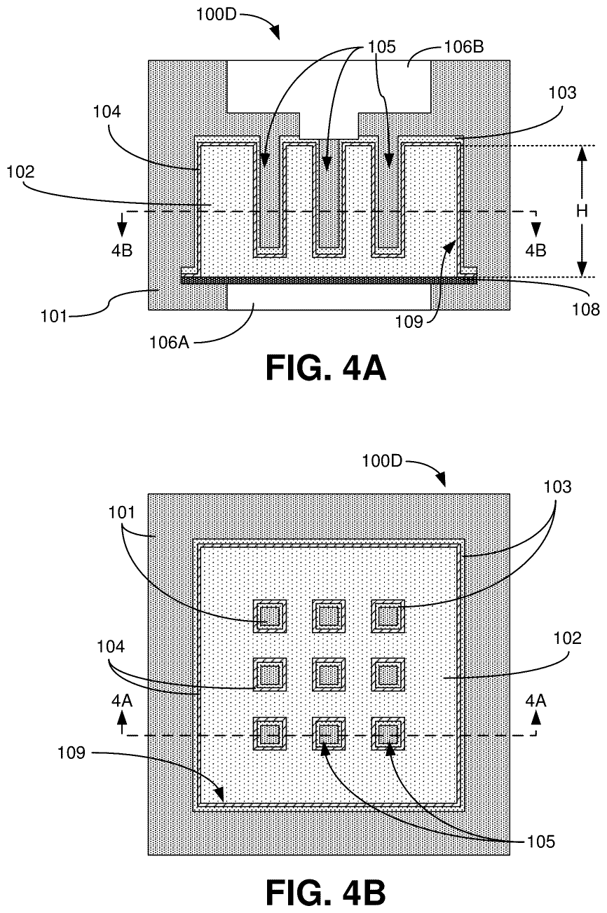

FIGS. 4A and 4B illustrate a side view and a plan view, respectively, of some embodiments of a 3D-MIM capacitor structure 100D having a bulk conductive element 102 including shallow trenches 105 with vertical sidewalls, according to the present disclosure. In a manner similar to that described above in relation to 3D-MIM capacitor structure 100B of FIGS. 2A and 2B, in some embodiments, shallow trenches 105 may extend at least halfway between an upper side of bulk conductive element 102 and a lower side of bulk conductive element (e.g., at conductive barrier layer 108). Accordingly, the depth of trenches 105 may be greater than 0.5H and less than H, as illustrated in FIG. 4A. Further, in some embodiments, the depth of shallow trenches 105 may be selected such that 3D-MIM capacitor structure 100B may provide an associated amount of capacitance (e.g., by altering the overall surface area of trenches 105, within which dielectric element 104 and conductive element 103 are deposited).

Additionally, in some embodiments, like the vertical sidewalls of trenches 105 of 3D-MIM capacitor structure 100C of FIGS. 3A and 3B, trenches 105, as well as outer wall 109, of 3D-MIM capacitor structure 100C may be formed in bulk conductive element 102 by way of a vertical (e.g., anisotropic) etching technique. In some embodiments, the vertical sidewalls and outer wall 109 may facilitate the deposition of additional structural layers, such as a dielectric element 104 and second conductive element 103.

Other aspects regarding bulk conductive element 102 (e.g., including trenches 105 and outer wall 109), dielectric element 104, conductive element 103, conductive barrier layer 108, first electrode 106A, second electrode 106B, and dielectric structure 101 of 3D-MIM capacitor structure 100A, as illustrated in FIGS. 1A and 1B and as discussed above, may be applicable to 3D-MIM capacitor structure 100B of FIGS. 2A and 2B.

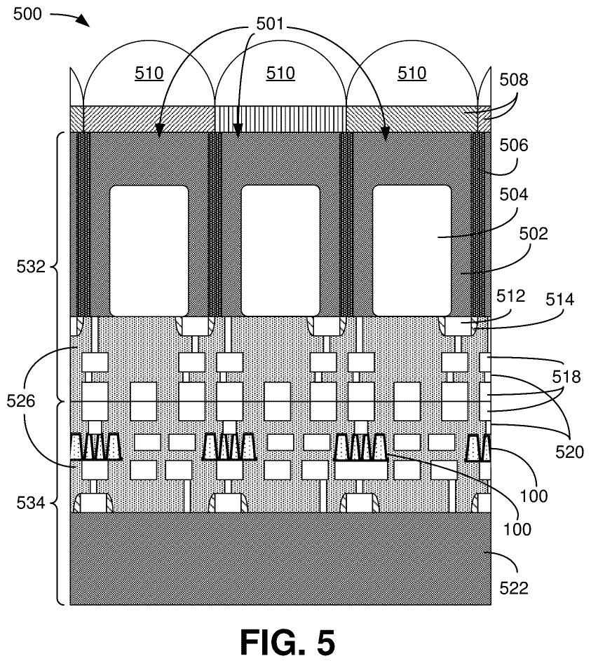

FIG. 5 illustrates a side view of some embodiments of a CMOS image sensor (CIS) IC device 500 including a plurality of 3D-MIM capacitor structures 100, each having a bulk conductive element 102, according to the present disclosure. While CIS IC device 500 represents a particular example of an IC device in which one or more 3D-MIM capacitor structures 100 may be implemented, many other types of IC devices may implement one or more 3D-MIM capacitor structures 100 in other embodiments.

CIS IC device 500, in some embodiments, may include an upper IC layer 532 and a lower IC layer 534 that may be bonded together (e.g., by way of thermal bonding). Generally, upper IC layer 532 may include a number of pixel cells 501, while lower IC layer 534 may include per-pixel circuitry and/or in-pixel circuitry that is coupled to pixel cells 501, which are described in greater detail below.

Further illustrated in FIG. 5 are lenses (e.g., microlenses) 510 and filters 508, where one lens 510 and one associated filter 508 may be disposed over a corresponding pixel cell 501 to focus and subsequently filter light provided to pixel cell 501. In some embodiments, each pixel cell 501 may corresponding with a filter 508 of a particular color (e.g., red, green, or blue). However, other colors or wavelength bands may be associated with filters 508 in other embodiments.

Upper IC layer 102A may include a substrate 502 and a dielectric layer structure 526. In some embodiments, substrate 502 of upper IC layer 532, as well as substrate 522 of lower IC layer 534, may be a semiconductor substrate that may include silicon (Si) and/or another semiconductor material. Further, in some embodiments, dielectric layer structure 526 of upper IC layer 532, as well as dielectric layer structure 526 of lower IC layer 534, may include one or more dielectric materials, including, but not limited to, silicon oxide (SiOₓ) (e.g., silicon dioxide (SiO₂)), silicon nitride (SiN), silicon carbide (SiC), carbon doped silicon dioxide, silicon oxynitride, borosilicate glass (BSG), phosphorus silicate glass (PSG), borophosphosilicate glass (BPSG), fluorosilicate glass (FSG), undoped silicate glass (USG), a porous dielectric material, or the like.

Substrate 502 of upper IC layer 532 may include a photosensitive region 504 for each pixel cell 501. Each photosensitive region 504 may form a corresponding photodetector (e.g., a photodiode) with the surrounding regions of substrate 502. In some embodiments, photosensitive regions 504 are formed proximate a lower side of substrate 502 adjacent to which dielectric layer structure 526 of upper IC layer 532 is disposed.

Also in substrate 502 of upper IC layer 532, in some embodiments, a plurality of barrier structures 506 may be disposed between adjacent pixel cells 501 (e.g., to provide electrical and/or optical isolation between pixel cells 501, such as to reduce signal crosstalk therebetween).

Further, as illustrated in FIG. 5, in some embodiments, within dielectric layer structure 526 of upper IC layer 532, at an upper side proximate substrate 502, a transfer gate structure 512, and possibly a spacer structure 514, may be disposed proximate a photosensitive region 504 and a floating diffusion region proximate the lower side of substrate 502. In some embodiments, transfer gate structure 512 may include a gate oxide material with a connecting conductive structure (e.g., polycrystalline silicon, a metallic conductor, or another electrically conducting material).

In some embodiments, dielectric layer structure 526 of upper IC layer 532 may also include a plurality of conductive layer structures 518 and interconnecting via structures 520. Similarly, dielectric layer structure 526 of lower IC layer 534 may include a plurality of conductive layer structures 518 and interconnecting via structures 520. In some embodiments, at a boundary of upper IC layer 532 and lower IC layer 534, a plurality of conductive layer structures 518 at a lower side of dielectric layer structure 526 of upper IC layer 532 and a corresponding plurality of conductive layer structures 518 at an upper side of dielectric layer structure 526 of lower IC layer 534 may make contact in response to a bonding of upper IC layer 532 to lower IC layer 534. In some embodiments, conductive layer structures 518 and associated conductive via structure 520 may include a metal (e.g., copper (Cu) or aluminum (Al)), metal alloy, or another conductive material.

Lower IC layer 534, as depicted in FIG. 5, may also include its own substrate 522 (e.g., a silicon substrate or another semiconductor substrate). Within lower IC layer 534, substrate 502 and dielectric layer structure 526 may include one or more processing circuits. Such processing circuits, in some embodiments, may include a plurality of per-pixel circuits, such as a source follower transistor, a row select transistor, and/or a reset transistor for each pixel cell 501. Further, in some embodiments, the processing circuits may further include a conversion gain (e.g., high/mid/low conversion gain) circuit, a voltage domain global shutter circuit, and/or other circuitry. Such circuits may be interconnected by way of one or more conductive layer structures 518 and/or conductive via structures 520 in dielectric layer structure 526 of lower IC layer 534.

In some embodiments, one or more of the processing circuits of lower IC layer 534 may include one or more 3D-MIM capacitor structures 100 (e.g., 3D-MIM capacitor structures 100A, 100B, 100C, and/or 100D of FIGS. 1A and 1B, FIGS. 2A and 2B, FIGS. 3A and 3B, and FIGS. 4A and 4B, respectively). More specifically, in some embodiments, one or more 3D-MIM capacitor structures 100 may serve as a feedback capacitor for a gain circuit (e.g., a multi-mode gain circuit) for each pixel cell 501, as electron storage for each pixel cell 501 (e.g., as may be employed in a global shutter sensor, in which all pixel cells 501 are exposed to light and subsequently read simultaneously), or for other processing circuits associated with one or more pixel cells 501.

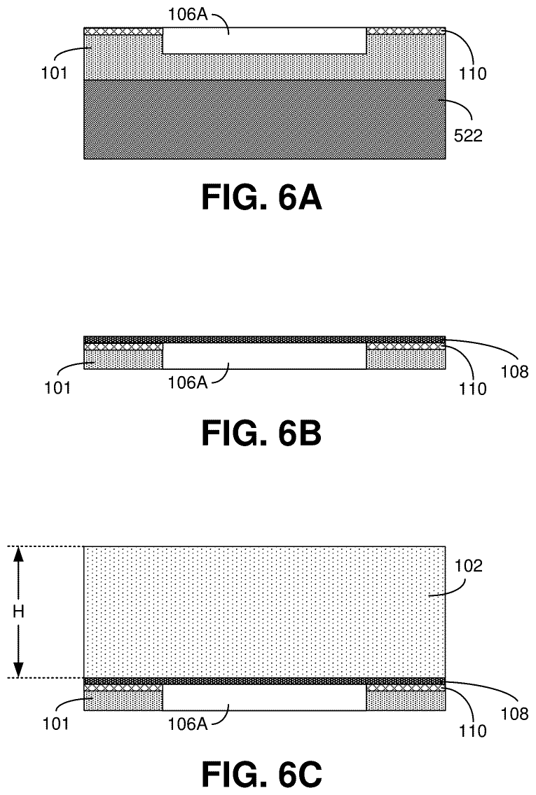

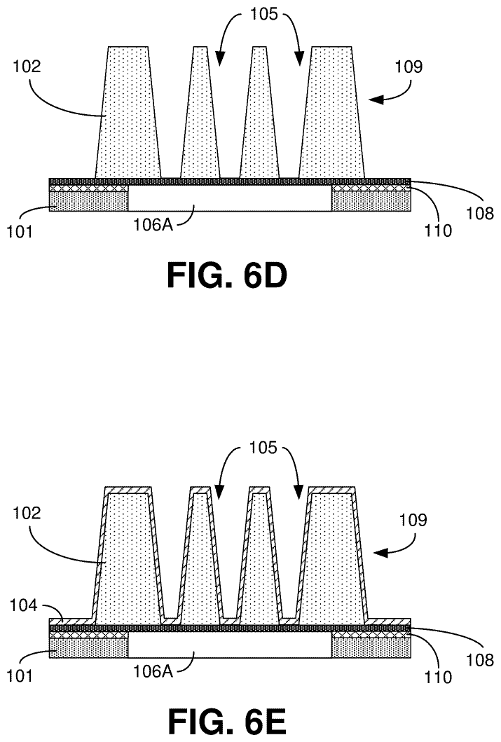

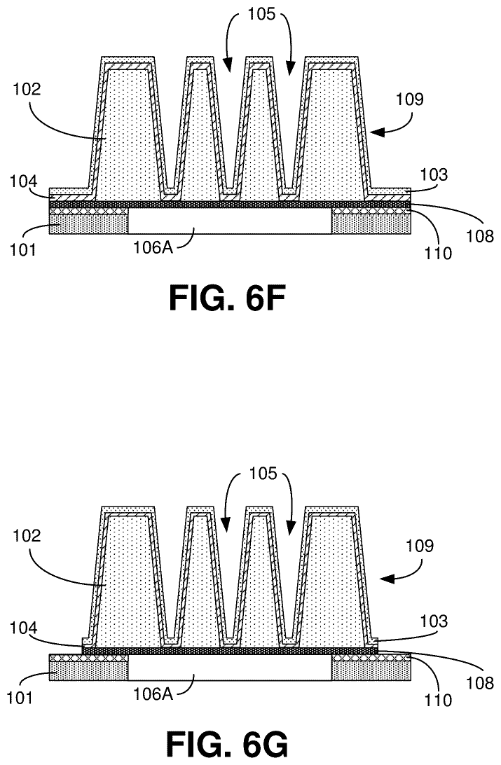

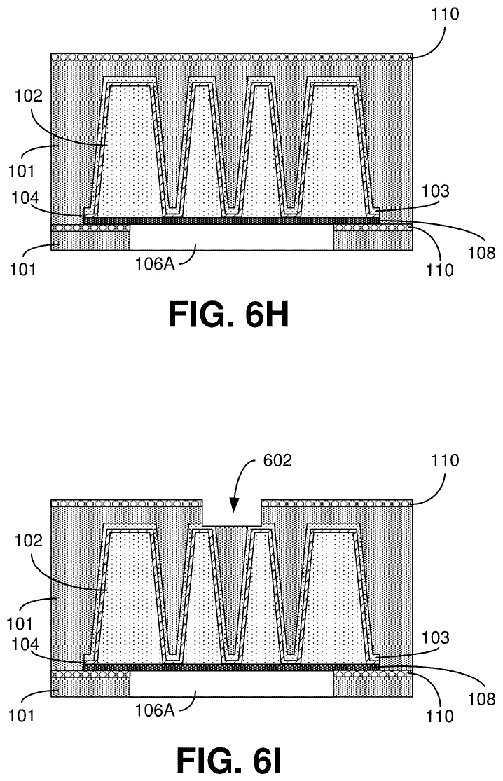

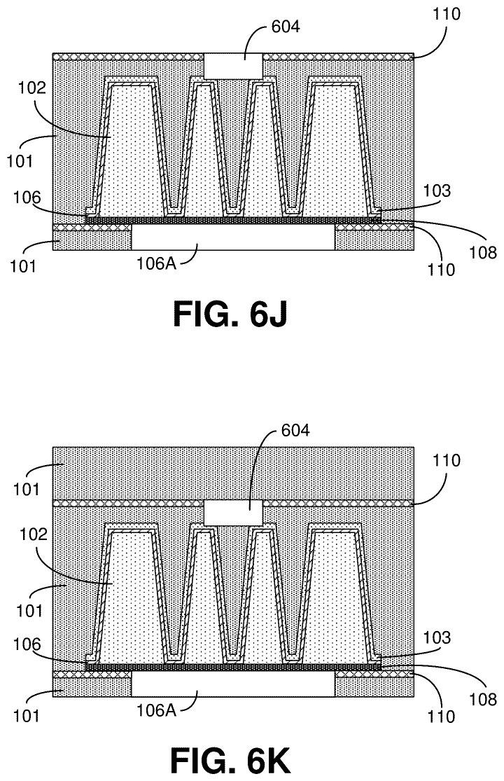

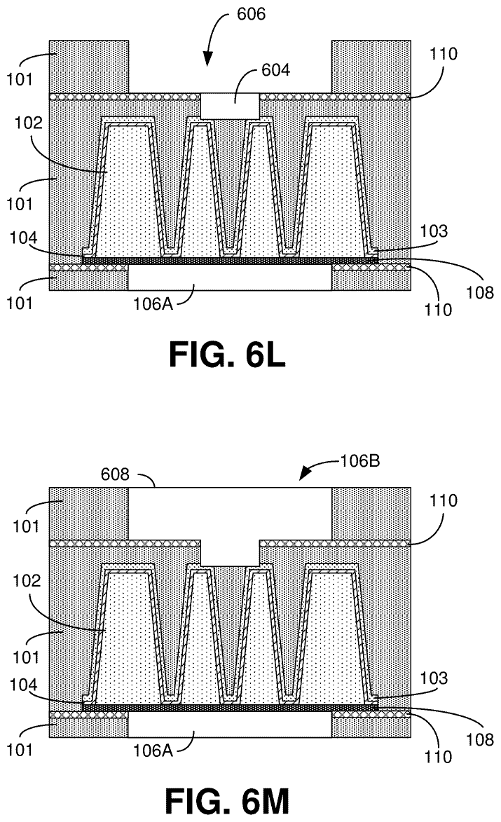

FIGS. 6A through 6M illustrate various side views of some embodiments of an IC device including a 3D-MIM capacitor structure (e.g., 3D-MIM capacitor structure 100 having a bulk conductive element 102) at various stages of manufacture, according to the present disclosure. Although FIGS. 6A through 6M are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

FIG. 6A illustrates a first electrode 106A disposed within a dielectric structure 101. In some embodiments, first electrode 106A and dielectric structure 101 may be formed over a substrate 522 (e.g., a silicon (Si) substrate). In some embodiments, first electrode 106A may be a portion of a conductive layer of an IC device (e.g., a conductive layer structure 518 of a CIS IC device 500, as shown in FIG. 5) by which other electrical connections between circuits within IC device may be made. Dielectric structure 101 may include one or more dielectric materials, including, but not limited to, silicon oxide (SiOₓ) (e.g., silicon dioxide (SiO₂)), silicon nitride (SiN), and silicon carbide (SiC)). Additionally, in some embodiments, an etch stop layer 110 may be formed (e.g., deposited) on dielectric structure 101 (e.g., prior to the formation of first electrode 106A).

FIG. 6B illustrates the forming (e.g., deposition) of a conductive barrier layer 108 over first electrode 106A and dielectric structure 101. In some embodiments, conductive barrier layer 108 may include tantalum (Ta), tantalum nitride (TaN), a combination thereof, one or more metals or metal alloys, and/or one or more other conductive materials.

FIG. 6C illustrates the forming (e.g., deposition) of a bulk conductive element 102 over conductive barrier layer 108. As indicated above, in some embodiments, a height H of bulk conductive element 102 may be in the range of approximately 0.2 μm to approximately 2.0 μm, although other heights H for bulk conductive element 102 are also possible. Further, in some embodiments, bulk conductive element 102 may include titanium nitride (TiN), an aluminum-copper (AlCu) alloy, tungsten (W), and/or another metal or metal alloy, and/or another conductive material. Also, in some embodiments, bulk conductive element 102 may be formed within a region of the IC device in which a conductive (e.g., metal) layer is deposited in other regions laterally adjacent to bulk conductive element 102.

FIG. 6D illustrates the removal (e.g., by photolithography and etching) of portions of bulk conductive element 102 to form a plurality of trenches 105 (e.g., where each trench 105 includes one or more sidewalls) and an outer wall 109 in bulk conductive element 102. In some embodiments, as depicted in FIG. 6D, the plurality of trenches 105 may extend completely through bulk conductive element 102 to conductive barrier layer 108. In other embodiments, one or more trenches 105 may extend less than completely through bulk conductive element 102 (e.g., greater than approximately 0.5 H and less than approximately 1.0 H in depth from an upper side of bulk conductive element 102). Further, in some embodiments, as shown in FIG. 6D, the sidewalls of trenches 105 and outer wall 109 may be angled relative to a vertical orientation. In yet other embodiments, the sidewalls of trenches 105 and outer wall 109 may possess a vertical orientation.

FIG. 6E illustrates the forming (e.g., by conformal deposition) of a dielectric element 104 over bulk conductive element 102. More specifically, dielectric element 104 may be conformally deposited into trenches 105 (e.g., onto the bottom and sidewalls of trenches 105), on an upper side of bulk conductive element 102, on outer wall 109, and possibly on other exposed portions of conductive barrier layer 108. In some embodiments, dielectric element 104 may include a high-κ dielectric material, such as hafnium silicate (HfO₆Si₂), zirconium silicate (ZrSiO₄), hafnium dioxide (HfO₂), zirconium dioxide (ZrO₂), and/or the like. In other embodiments, dielectric element 104 may include other dielectric materials that are not high-κ dielectric or insulating materials.

FIG. 6F illustrates the forming (e.g., by conformal deposition) of a conductive element 103 over dielectric element 104. In some embodiments, conductive element 103 may be conformally deposited into trenches 105, over an upper side of bulk conductive element 102, over outer wall 109, and possibly over other exposed portions of dielectric element 104. In some embodiments, conductive element 103 may include titanium nitride (TiN), an aluminum-copper (AlCu) alloy, tungsten (W), and/or another metal or metal alloy, and/or another conductive material.

FIG. 6G illustrates the removal (e.g., by photolithography and etching) of portions of conductive element 103, dielectric element 104, and/or conductive barrier layer 108 (e.g., down to etch stop layer 110) over bulk conductive element 102. In some embodiments, the lateral extent of such removal may reach outward to or beyond an edge of outer wall 109 of bulk conductive element 102. In some embodiments, the removal may be performed by forming a mask over conductive element 103 and then performing an etching process with the mask in place.

FIGS. 6H through 6M collectively illustrate the forming of a second electrode 106B for 3D-MIM capacitor structure 100A, in some embodiments. More specifically, FIG. 6H illustrates the forming (e.g., by deposition) of additional dielectric material, and possibly an upper etch stop layer 110, to dielectric structure 101 to cover or encapsulate conductive barrier layer 108, bulk conductive element 102, dielectric element 104, and/or conductive element 103. Further, FIG. 6I illustrates the removal (e.g., by photolithography and etching) of an upper portion 602 of dielectric structure 101 and upper etch stop layer 110, and FIG. 6J illustrates the forming (e.g., deposition) of a lower portion 604 of second electrode 106B. Similarly, FIG. 6K illustrates the forming (e.g., by deposition) of yet additional dielectric material to dielectric structure 101 to cover lower portion 604 of second electrode 106B and upper etch stop layer 110. Thereafter, FIG. 6L illustrates the removal (e.g., by photolithography and etching) of an upper portion 606 of dielectric structure 101 (e.g., downward to upper etch stop layer 110), and FIG. 6M illustrates the forming (e.g., deposition) of a upper portion 608 of second electrode 106B. In some embodiments, one or more of these processing operations may be followed by a planarization operation (e.g., via chemical mechanical planarization (CMP)).

In some embodiments, the operations associated with FIGS. 6H through 6M may be performed in parallel with the formation of conductive (e.g., metal) layer structures and conductive via structures employed as electrical connection structures in an IC device (e.g., conductive layer structures 518 and interconnecting via structures 520 of CIS IC device 500 of FIG. 5).

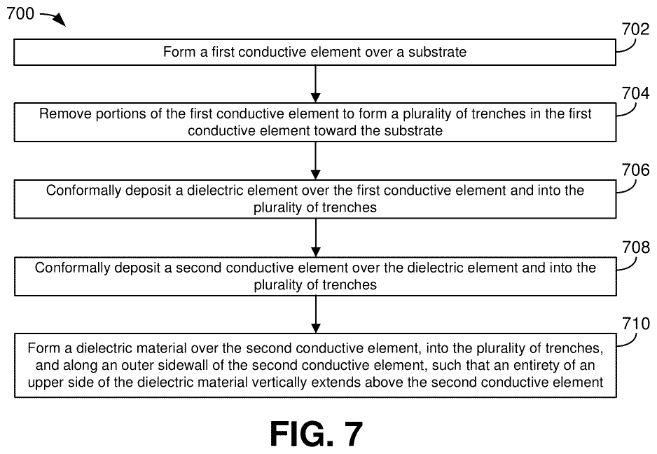

FIG. 7 illustrates a methodology 700 of forming an IC device including a 3D-MIM capacitor structure (e.g., 3D-MIM capacitor structure 100A, 100B, 100C, and 100D of FIGS. 1A and 1B, FIGS. 2A and 2B, FIGS. 3A and 3B, and FIGS. 4A and 4B, respectively) that includes a bulk conductive element (e.g., bulk conductive element 102), in accordance with some embodiments. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At Act 702, for example, a first conductive element (e.g., bulk conductive element 102 of FIG. 6C) may be formed over a substrate (e.g., substrate 522 of FIG. 5). FIG. 6C illustrates a cross-sectional view of some embodiments corresponding to Act 702.

At Act 704, a part of the first conductive element is removed to form a plurality of trenches (e.g., trenches 105) extending within the first conductive element toward the substrate. FIG. 6D illustrates a cross-sectional view of some embodiments corresponding to Act 704.

At Act 706, a dielectric element (e.g., dielectric element 104 of FIG. 6E) may be conformally deposited over the first conductive element and into the plurality of trenches. FIG. 6E illustrates a cross-sectional view of some embodiments corresponding to Act 706.

At Act 708, a second conductive element (e.g., conductive element 103 of FIG. 6F) may be conformally deposited over the dielectric element and into the plurality of trenches. FIG. 6F illustrates a cross-sectional view of some embodiments corresponding to Act 708.

At Act 710, a dielectric material (e.g., the upper layer of dielectric structure 101 of FIG. 6H) is formed the over the second conductive element, into the plurality of trenches, and along an outer sidewall of the second conductive element, such that an entirety of an upper side of the dielectric material vertically extends above the second conductive element. FIG. 6H illustrates a cross-sectional view of some embodiments corresponding to Act 708.

Some embodiments relate to an IC device. The IC device includes a substrate and a capacitor structure. The capacitor structure includes a first conductive element disposed over the substrate. The first conductive element includes a plurality of trenches extending downward from an upper side of the first conductive element toward the substrate. A thickness of the first conductive element between adjacent ones of the plurality of trenches is greater than or equal to a depth of the plurality of trenches. The capacitor structure further includes a dielectric element disposed on the upper side of the first conductive element and extending into the plurality of trenches, and a second conductive element disposed on the dielectric element and extending into the plurality of trenches.

Some embodiments relate to another IC device. The IC device includes a substrate and a capacitor structure. The capacitor structure includes a first conductive element disposed over the substrate. The first conductive element includes a first plurality of trenches extending from an upper side of the first conductive element toward the substrate. A thickness of the first conductive element between adjacent ones of the first plurality of trenches is greater than or equal to a depth of the first plurality of trenches. Each of the first plurality of trenches is separate in a plan view of the IC device. The capacitor structure further includes a dielectric element disposed on the upper side of the first conductive element and forming a second plurality of trenches. Each of the second plurality of trenches extends into a corresponding one of the first plurality of trenches. The capacitor structure also includes a second conductive element disposed on the dielectric element and forming a third plurality of trenches. Each of the third plurality of trenches extends into a corresponding one of the second plurality of trenches.

Some embodiments relate to a method. The method includes forming a first conductive element over a substrate; forming a first conductive element over a substrate; removing portions of the first conductive element to form a plurality of trenches in the first conductive element toward the substrate; conformally depositing a dielectric element over the first conductive element and into the plurality of trenches; and conformally depositing a second conductive element over the dielectric element and into the plurality of trenches.

It will be appreciated that in this written description, as well as in the claims below, the terms “first”, “second”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) device, comprising:
a substrate; and
a capacitor structure comprising:
a first conductive element disposed over the substrate, the first conductive element comprising a plurality of trenches extending downward from an upper side of the first conductive element toward the substrate, a thickness of the first conductive element between adjacent ones of the plurality of trenches being greater than or equal to a depth of the plurality of trenches;
a dielectric element disposed on the upper side of the first conductive element and extending into the plurality of trenches; and
a second conductive element disposed on the dielectric element and extending into the plurality of trenches.

2. The IC device of claim 1, further comprising:
a first electrode disposed over the substrate, wherein the first electrode is under, and conductively coupled with, the first conductive element; and
a second electrode disposed over, and conductively coupled with, the second conductive element.

3. The IC device of claim 2, wherein the second electrode contacts a region of the second conductive element surrounding at least one of the plurality of trenches in a plan view of the IC device.

4. The IC device of claim 2, further comprising:
a conductive barrier layer disposed on the first electrode, wherein the first conductive element is disposed on the conductive barrier layer.

5. The IC device of claim 4, wherein the first electrode contacts a region of the conductive barrier layer surrounding the plurality of trenches in a plan view of the IC device.

6. The IC device of claim 4, wherein each of the plurality of trenches extends to the conductive barrier layer.

7. The IC device of claim 4, wherein each of the plurality of trenches extends greater than half a distance from the upper side of the first conductive element to the conductive barrier layer, but less than an entirety of the distance from the upper side of the first conductive element to the conductive barrier layer.

8. The IC device of claim 1, wherein a sidewall of at least one of the plurality of trenches comprises a vertical sidewall.

9. The IC device of claim 1, wherein a sidewall of at least one of the plurality of trenches comprises an angled sidewall.

10. The IC device of claim 1, wherein at least one of the plurality of trenches is rectangular in a plan view of the IC device.

11. The IC device of claim 1, wherein at least one of the plurality of trenches is circular in a plan view of the IC device.

12. The IC device of claim 1, wherein the plurality of trenches are arranged in a two-dimensional array in a plan view of the IC device.

13. An integrated circuit (IC) device, comprising:
a substrate; and
a capacitor structure comprising:
a first conductive element disposed over the substrate, the first conductive element comprising a first plurality of trenches extending from an upper side of the first conductive element toward the substrate, a thickness of the first conductive element between adjacent ones of the first plurality of trenches being greater than or equal to a depth of the first plurality of trenches, each of the first plurality of trenches being separate in a plan view of the IC device;
a dielectric element disposed on the upper side of the first conductive element and forming a second plurality of trenches, each of the second plurality of trenches extending into a corresponding one of the first plurality of trenches; and
a second conductive element disposed on the dielectric element and forming a third plurality of trenches, each of the third plurality of trenches extending into a corresponding one of the second plurality of trenches.

14. The IC device of claim 13, wherein:
the first conductive element further comprises an outer wall extending from the upper side of the first conductive element toward the substrate and surrounding the first plurality of trenches;
the dielectric element comprises a first region covering the outer wall of the first conductive element; and
the second conductive element comprises a second region covering the first region of the dielectric element.

15. The IC device of claim 13, wherein each of the first plurality of trenches extends through the first conductive element.

16. The IC device of claim 13, wherein each of the first plurality of trenches extends at least halfway into the first conductive element.

17. A method comprising:
forming a first conductive element over a substrate;
removing portions of the first conductive element to form a plurality of trenches in the first conductive element toward the substrate;
conformally depositing a dielectric element over the first conductive element and into the plurality of trenches; and
conformally depositing a second conductive element over the dielectric element and into the plurality of trenches.

18. The method of claim 17, further comprising:
forming a first electrode over the substrate;
forming a conductive barrier layer on the first electrode prior to forming the first conductive element, the conductive barrier layer electrically connecting the first electrode to the first conductive element; and
forming a second electrode over the second conductive element, the second electrode contacting the second conductive element.

19. The method of claim 18, further comprising:
forming a dielectric material over the second conductive element, into the plurality of trenches, and along an outermost sidewall of the second conductive element, such that an entirety of an upper side of the dielectric material vertically extends above the second conductive element.

20. The method of claim 18, wherein forming the second electrode comprises:
forming a conductive via over the second conductive element, the conductive via contacting the second conductive element; and
forming a conductive structure on the conductive via.
